(19) United States
(12) Patent Application Publication
(10) Pub. No.: US 2025/0040096 A1
(43) Pub. Date: Jan. 30, 2025

(54) ELECTRONIC DEVICE

(71) Applicant: Wistron NeWeb Corporation, Hsinchu (TW)

(72) Inventors: Yu-Fu KU, Hsinchu (TW); Cheng-Yu YEH, Hsinchu (TW)

(21) Appl. No.: 18/391,912

(22) Filed: Dec. 21, 2023

(30) Foreign Application Priority Data
Jul. 27, 2023 (TW) 112128229

(51) Int. Cl. H05K 7/20

(52) U.S. Cl. CPC H05K 7/2039

(57) ABSTRACT

An electronic device includes a shell element, at least one electronic element, a printed circuit board, and an anti-scalding mask. The shell element has an accommodating space and a metal surface. At least one electronic element is disposed in the accommodating space. The printed circuit board is disposed in the accommodating space and is electrically connected to the at least one electronic element. The anti-scalding mask covers and is disposed on the metal surface. The anti-scalding mask is made of a low thermal conductivity material, and a thermal conductivity of the low thermal conductivity material is less than or equal to 20 W/mK.

### RELATED APPLICATIONS

This application claims the benefit of priority to Taiwan Patent Application Serial No. 112128229, filed on Jul. 27, 2023. The entire content of the above identified application is incorporated herein by reference.

### BACKGROUND

### Technical Field

The present disclosure relates to an electronic device, in particular to an electronic device with an anti-scalding effect.

### Description of Related Art

Electronic devices operate by allowing electric current to pass through their electronic components. During the operation, some of the electrical energy is converted into heat, raising the temperature of the electronic device. Users may also come into contact with the electronic devices that have become too hot, posing a risk of scald.

In view of this, in order to solve the increasing heat flux problem of electronic devices, shells made of plastic materials are applied on the electronic devices. However, the plastic materials are insufficient for meeting the heat dissipation requirements of electronic devices. Consequently, the electronic devices with metal shells have been developed to aid in heat dissipation. Nevertheless, according to the safety standard IEC-62368 for electronic products, the permissible touch temperature for the metal shells is much lower than that of the plastic shells. This often leads to a dilemma in electronic product design, as it becomes challenging to balance the touch temperature and the component temperature. Furthermore, the desktop electronic devices like computers, monitors, and laptops are closely integrated into people's lives and are more likely to be touched by users. Therefore, the touch temperature specification for these electronic devices needs to be strictly regulated to reduce the risk of users inadvertently touching and getting scaled by the device.

Therefore, finding an effective way to dissipate heat while simultaneously preventing users from accidentally touching hot electronic devices has become a continuing focus of research for professionals in the relevant industries.

### SUMMARY

According to one aspect of the present disclosure, an electronic device includes a shell element, at least one electronic element, a printed circuit board, and an anti-scalding mask. The shell element has an accommodating space and a metal surface. The at least one electronic element is disposed in the accommodating space. The printed circuit board is disposed in the accommodating space and is electrically connected to the at least one electronic element. The anti-scalding mask covers and is disposed on the metal surface and includes a plurality of vents. The anti-scalding mask is made of a low thermal conductivity material, and a thermal conductivity of the low thermal conductivity material is less than or equal to 20 W/mK.

According to another aspect of the present disclosure, an electronic device includes a shell element, at least one electronic element, a printed circuit board, and an anti-scalding mask. The shell element has an accommodating space and a metal surface. The shell element includes a plurality of fins. The plurality of fins are separately disposed on the metal surface. The at least one electronic element is disposed in the accommodating space. The printed circuit board is disposed in the accommodating space and is electrically connected to the at least one electronic element. The anti-scalding mask covers and is disposed on the metal surface and includes a plurality of vents. The anti-scalding mask is made of a low thermal conductivity material, and a thermal conductivity of the low thermal conductivity material is less than or equal to 20 W/mK.

According to further another aspect of the present disclosure, an electronic device includes a shell element, at least one electronic element, a printed circuit board, and an anti-scalding mask. The shell element has an accommodating space and a metal surface, and the shell element includes a plurality of fins. The plurality of fins are separately disposed on the metal surface. The at least one electronic element is disposed in the accommodating space. The printed circuit board is disposed in the accommodating space and is electrically connected to the at least one electronic element. The anti-scalding mask covers and is disposed on the metal surface. An air gap is defined by a peripheral portion of the anti-scalding mask and the shell element. The anti-scalding mask is made of a low thermal conductivity material, and a thermal conductivity of the low thermal conductivity material is less than or equal to 20 W/mK.

### BRIEF DESCRIPTION OF THE DRAWINGS

The present disclosure can be more fully understood by reading the following detailed description of the embodiment, with reference made to the accompanying drawings as follows:

FIG. 1 is a schematic view of an electronic device according to one embodiment of the present disclosure.

FIG. 2 is an exploded view of the electronic device as shown in FIG. 1.

FIG. 3 is another exploded view of the electronic device as shown in FIG. 1.

FIG. 4 is a schematic view of an anti-scalding mask of the electronic device as shown in FIG. 1.

FIG. 5A is a schematic view of a projection of a first part of the anti-scalding mask as shown in FIG. 4 along a first direction.

FIG. 5B is a schematic view of a projection of a second part of the anti-scalding mask as shown in FIG. 4 along the first direction.

FIG. 6 is a schematic view of a projection of the anti-scalding mask as shown in FIG. 4 along a second direction.

FIG. 7 is an exploded view of the electronic device according to another embodiment of the present disclosure.

FIG. 8 is an exploded view of the electronic device as shown in FIG. 7.

FIG. 9 is a cross-sectional view of the electronic device as shown in FIG. 7 along Line 9-9.

FIG. 10 is a schematic view of an arrangement of fins of the electronic device as shown in FIG. 7.

FIG. 11 is an enlarged view of the arrangement of the fins and vents of the electronic device as shown in FIG. 7.

FIG. 12A is a schematic view of fins according to further another embodiment of the present disclosure.

FIG. 12B is a schematic view of fins according to yet another embodiment of the present disclosure.

FIG. 12C is a schematic view of fins according to yet another embodiment of the present disclosure.

FIG. 12D is a schematic view of fins according to yet another embodiment of the present disclosure.

FIG. 13 is a schematic view of an electronic device according to yet another embodiment of the present disclosure.

FIG. 14 is a schematic view of an electronic device according to yet another embodiment of the present disclosure.

FIG. 15 is an exploded view of the electronic device as shown in FIG. 14.

FIG. 16 is another exploded view of the electronic device as shown in FIG. 14.

FIG. 17 is a schematic view of a projection of the electronic device as shown in FIG. 14 along a first direction.

FIG. 18 is a schematic view of a projection of the electronic device as shown in FIG. 14 along a second direction.

### DETAILED DESCRIPTION

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like. In addition, the term “couple” in the present disclosure includes any direct and indirect electrical connection means.

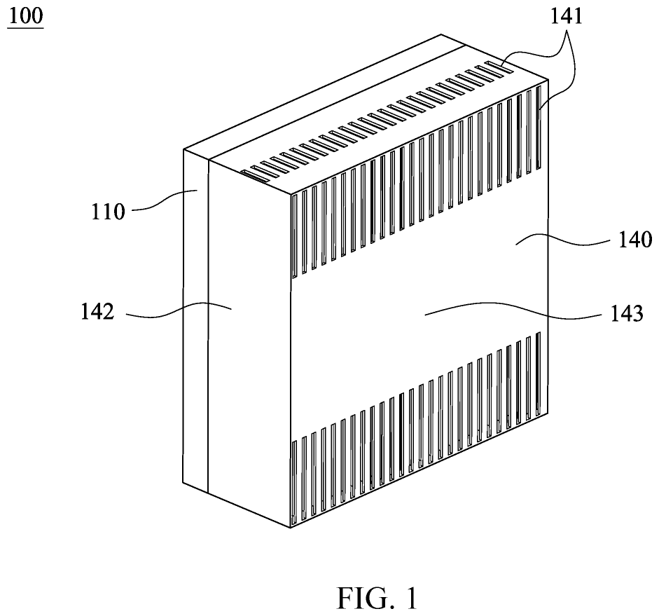

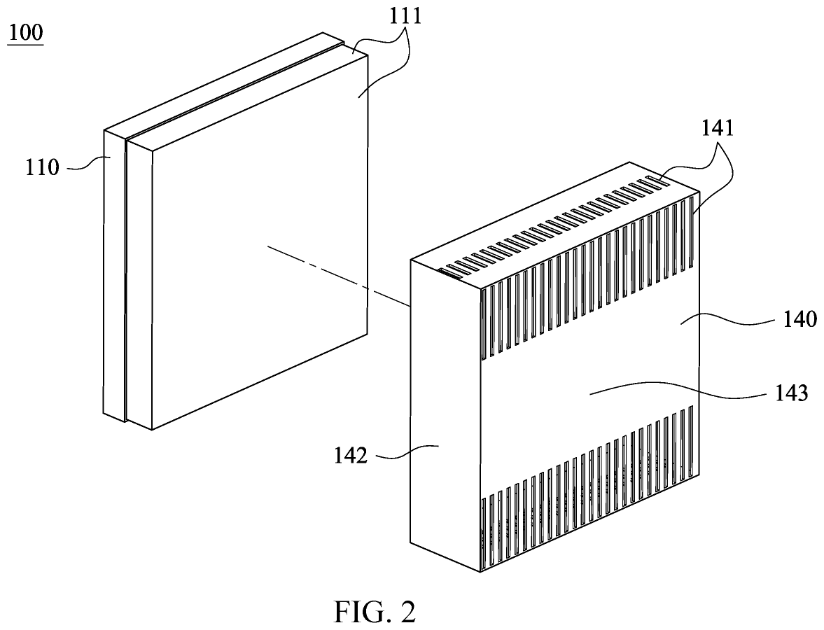

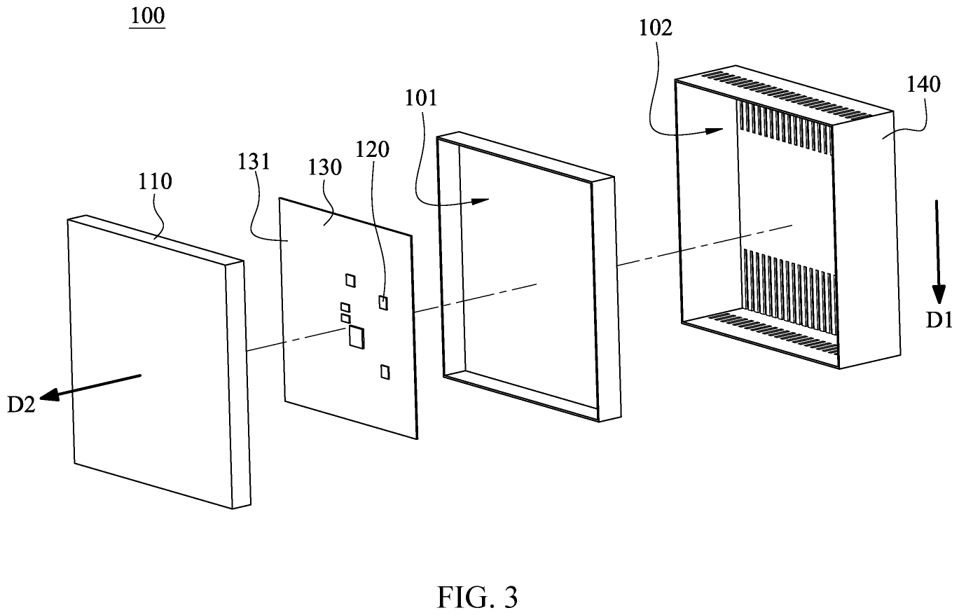

Reference is made to FIG. 1, FIG. 2, and FIG. 3. FIG. 1 is a schematic view of an electronic device 100 according to one embodiment of the present disclosure. FIG. 2 is an exploded view of the electronic device 100 as shown in FIG. 1. FIG. 3 is another exploded view of the electronic device 100 as shown in FIG. 1. The electronic device 100 includes a shell element 110, at least one electronic element 120, a printed circuit board 130, and an anti-scalding mask 140.

The shell element 110 has an accommodating space 101 (reference is shown in FIG. 3) and a metal surface 111. In detail, the shell element 110 is a component of the electronic device 100 and is configured to isolate the external environment, and the shell element 110 can be further divided into a non-metallic shell part (reference number is omitted) and a metal shell part (reference number is omitted). The non-metallic shell part has an excellent anti-scalding effect, while the metal shell part helps to dissipate heat, and the surface of the metal shell part is the metal surface 111 of the present disclosure (which includes the surface of the metallic shell part which is different from the direction toward the non-metallic shell part and the surface of the non-metallic shell part). Further, the shell element 110 can include air openings (not shown in the figure) according to actual needs. When the shell element 110 does not include the air opening, the characteristics of waterproof, dustproof, and low smoke generation of the electronic device 100 can be enhanced. When the shell element 110 includes the air openings, the efficiency of the heat dissipation can be further improved, but the present disclosure is not limited thereto.

As shown in FIG. 3, the electronic element 120 is disposed in an accommodating space 101 of the shell element 110. The printed circuit board 130 is also disposed in the accommodating space 101 and is electrically connected to the electronic element 120. The electronic element 120 can be but not limited to a chip, a resistor, a capacitive element, an inductive element, a potentiometer, a transformer, a triode or a diode. The printed circuit board 130 may be a circuit substrate including traces or other necessary components, but the disclosure is not limited thereto.

The anti-scalding mask 140 covers the metal surface 111, and the anti-scalding mask 140 includes a plurality of vents 141. As shown in FIG. 1, the vents 141 can be opened on different surfaces of the anti-scalding mask 140, and the vents 141 also can be only opened on a single surface of the anti-scalding mask 140 according to requirements. The plurality of vents 141 can be separately opened on the anti-scalding mask 140, but the present disclosure is not limited to the contents disclosed in the figures. Therefore, the electronic device 100 of the present disclosure can prevent the users from directly touching the metal surface 111 with high temperature by the arrangement that the anti-scalding mask 140 covers the metal surface 111 of the shell element 110, so that the risk of the users being scalded by the metal surface 111 can be effectively reduced. Further, by the arrangement of the multiple vents 141, it is favorable for dissipating the heat generated during the operation of the electronic device 100 through the vents 141 by the heat convection, and the overheating of the electronic device 100 can be avoided. Furthermore, the shape of the anti-scalding mask 140 can be a rectangle as shown in the electronic device 100, or it can be arc-shaped or polygonal etc., and the present disclosure is not limited to the contents disclosed in the figures.

The anti-scalding mask 140 is made of a low thermal conductivity material. The low thermal conductivity material can be a plastic, a wood, a rubber, a glass, or other materials with a thermal conductivity less than or equal to 20 W/mK. The anti-scalding mask 140 made of the low thermal conductivity material can meet the touch temperature specification specified by the safety standard of the electronic products and can prevent users from directly touching the metal surface 111 of the shell element 110 and getting scaled. Moreover, in the electronic device 100, since both the electronic element 120 and the printed circuit board 130 are disposed in the accommodating space 101 of the shell element 110, and the electronic element 120 is not disposed in the mask space 102 (reference is shown in FIG. 3) between the anti-scalding mask 140 and the shell element 110, there is no risk of the foreign objects falling to the interior of the electronic device 100. Thus, the size and the form of the vents 141 of the anti-scalding mask 140 cannot be limited to the safety standards of the electronics products, and a higher opening ratio can be configured on the anti-scalding mask 140 if the mechanical strength permits, or the size of the vents 141 can be increased, so that the heat dissipation efficiency of the electronic device 100 of the present disclosure can be further enhanced.

As shown in FIG. 1 and FIG. 2 again, the anti-scalding mask 140 can further include a sidewall structure 142 and a mask cover 143. One side of the sidewall structure 142 is connected to the shell element 110, the mask cover 143 is connected to another side of the sidewall structure 142, and the mask space 102 of the anti-scalding mask 140 is defined by the shell element 110, the sidewall structure 142, and the mask cover 143. At least one of the sidewall structure 142 and the mask cover 143 can include the vents 141. The vents 141 are communicated with the mask space 102. By the arrangement of the sidewall structure 142 and the mask cover 143, and the vents 141 are opened on at least one of the sidewall structure 142 and the mask cover 143, the space required for heat convection can be provided by the mask space 102, so that it is favorable for dissipating the heat of the electronic device 100 out of the shell element 110 through the vents 141. Further, as shown in FIG. 1 and FIG. 2, the vents 141 can be separated from each other and equidistantly disposed on the sidewall structure 142 or the mask cover 143, or both the sidewall structure 142 and the mask cover 143 include the vents 141, but the present disclosure is not limited thereto.

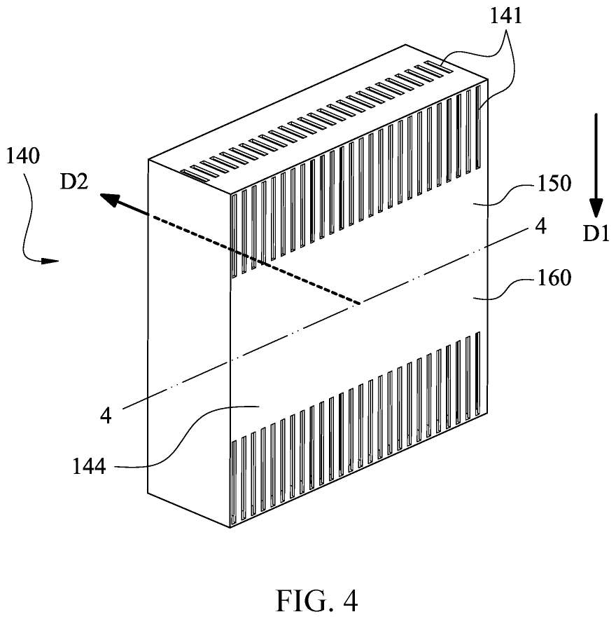

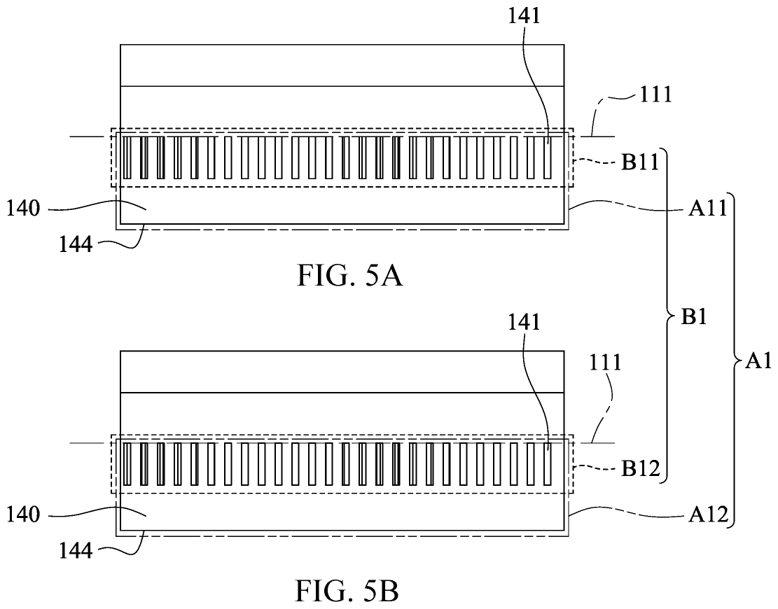

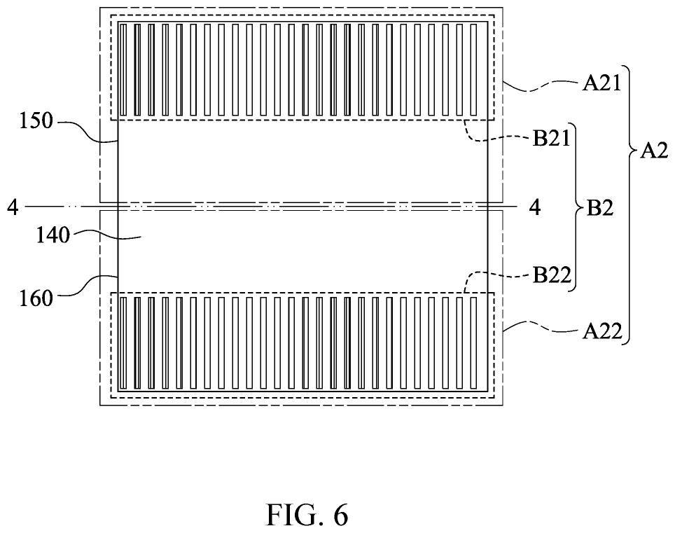

Reference is made to FIG. 3, FIG. 4, FIG. 5A, FIG. 5B, and FIG. 6 together. FIG. 4 is a schematic view of the anti-scalding mask 140 of the electronic device 100 as shown in FIG. 1. FIG. 5A is a schematic view of a projection of a first part 150 of the anti-scalding mask 140 as shown in FIG. 4 along a first direction D1. FIG. 5B is a schematic view of a projection of a second part 160 of the anti-scalding mask 140 as shown in FIG. 4 along the first direction D1. FIG. 6 is a schematic view of a projection of the anti-scalding mask 140 as shown in FIG. 4 along a second direction D2.

In the electronic device 100 of the present disclosure, the first direction D1 and the second direction D2 are defined. As shown in FIG. 3, the second direction D2 is perpendicular to an extending direction perpendicular to a circuit board surface 131 of the printed circuit board 130, and the first direction D1 is perpendicular to the second direction D2. When a projected area of the anti-scalding mask 140 along the first direction D1 is A1, a projected area of the anti-scalding mask 140 along the second direction D2 is A2, a projected area of the vents 141 along the first direction D1 is B1, and a projected area of the vents 141 along the second direction D2 is B2, the following condition can be satisfied: 5%≤(B1+B2)/(A1+A2). Therefore, the anti-scalding mask 140 can have the effects of heat dissipation and anti-scalding as well as an excellent mechanical strength, so that the electronic device 100 of the present disclosure has excellent market application potential. Further, in some embodiments, the following condition can be further satisfied: 12%≤(B1+B2)/(A1+A2)≤40%. Thus, the best balance of the heat dissipation, the anti-scalding and the mechanical strength can be achieved.

As shown in FIG. 4 again, the anti-scalding mask 140 can have a first part 150 and a second part 160. The first part 150 and the second part 160 are arranged in sequence along the first direction D1. In detail, the first part 150 and the second part 160 of the anti-scalding mask 140 are defined by a half of a height (i.e., height without bracket and external antennas etc.) of the main body of the electronic device 100 as a boundary (as shown in FIG. 4, the first part 150 and the second part 160 are distinguished by an imaginary line 4-4 at a half of the length of the anti-scalding mask 140 along the first direction D1). At least one of the vents 141 is opened on both the first part 150 and the second part 160.

As shown in FIG. 3, FIG. 5A, FIG. 5B and FIG. 6, when the electronic device 100 is projected along the first direction D1 and the second direction D2, respectively, a projected area of the first part 150 of the anti-scalding mask 140 along the first direction D1 is A11, a projected area of the first part 150 of the anti-scalding mask 140 along the second direction D2 is A21, a projected area of the vents 141 on the first part 150 along the first direction D1 is B11, and a projected area of the vents 141 on the first part 150 along the second direction D2 is B21, the following condition can be satisfied: 5%≤(B11+B21)/(A11+A21).

Furthermore, when a projected area of the second part 160 of the anti-scalding mask 140 along the first direction D1 is A12, a projected area of the second part 160 of the anti-scalding mask 140 along the second direction D2 is A22, a projected area of the vents 141 on the second part 160 along the first direction D1 is B12, and a projected area of the vents 141 on the second part 160 along the second direction D2 is B22, the following condition can be satisfied: 5%≤(B12+B22)/(A12+A22).

Specifically, the projected area A1 of the anti-scalding mask 140 along the first direction D1 is the sum of the projected area A11 of the first part 150 along the first direction D1 and the projected area A12 of the second part 160 along the first direction D1 (A1=A11+A12). The projected area A2 of the anti-scalding mask 140 along the second direction D2 is the sum of the projected area A21 of the first part 150 along the second direction D2 and the projected area A22 of the second part 160 along the second direction D2 (A2=A21+A22). The projected area B1 of the vents 141 along the first direction D1 is the sum of the projected area B11 of the vents 141 on the first part 150 along the first direction D1 and the projected area B12 of the vents 141 on the second part 160 along the first direction D1 (B1=B11+B12). The projected area B2 of the vents 141 along the second direction D2 is the sum of the projected area B21 of the vents 141 on the first part 150 along the second direction D2 and the projected area B22 of the vents 141 on the second part 160 along the second direction (B2=B21+B22). When the electronic device 100 is projected along the first direction D1 and the second direction D2, the ratios of the projected areas of different parts of the anti-scalding mask 140 respectively satisfy the conditions as mentioned, which can ensure that the first part 150 and the second part 160 of the anti-scalding mask 140 have excellent effect of heat dissipation and anti-scalding as well as mechanical strength, and thus the present disclosure has excellent market application potential. Further, in some embodiments, the electronic device 100 can also satisfy the following condition:

$$12 \% \leq ( B 11 + B 21 ) / ( A 11 + A 21 ) \leq 40 \% ;$$

$$or$$

$$12 \% \leq ( B 12 + B 22 ) / ( A 12 + A 22 ) \leq 40 \% .$$

Further, the projected area A1 of the anti-scalding mask 140 along the first direction D1 can be a projected area from the metal surface 111 to a surface 144 of the anti-scalding mask 140 (reference is shown in FIG. 5A and FIG. 5B, and the position of the surface 144 is shown in FIG. 4), so as to exclude the projected area where the anti-scalding mask 140 overlaps with the shell element 110. Hence, the ratio of the vents 141 to the anti-scalding mask 140 can be arranged more accurately so as to ensure the effects of heat dissipation and anti-scalding of the electronic device 100.

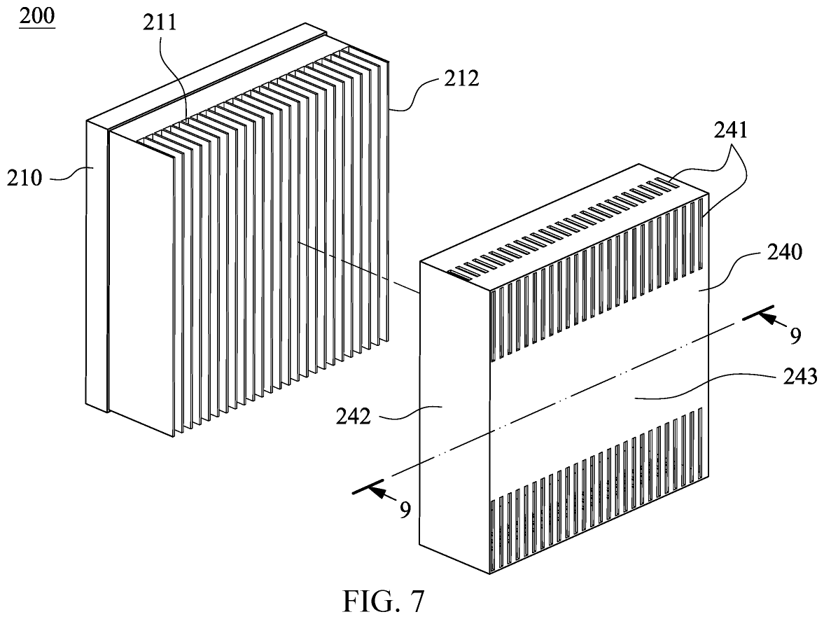

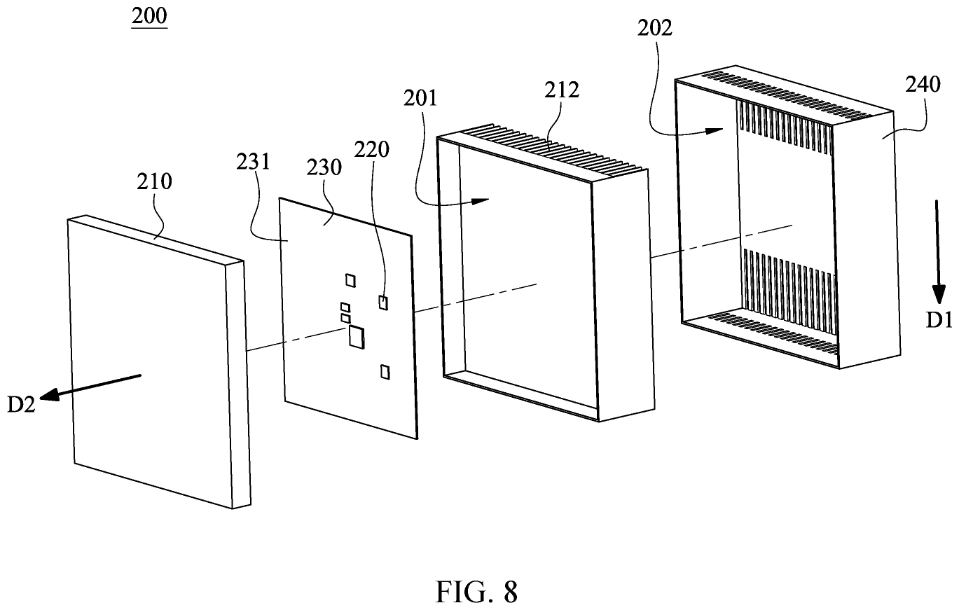

Reference is made to FIG. 7 and FIG. 8. FIG. 7 is an exploded view of an electronic device 200 according to another embodiment of the present disclosure. FIG. 8 is an exploded view of the electronic device 200 as shown in FIG. 7. The electronic device 200 includes a shell element 210, at least one electronic element 220, a printed circuit board 230, and an anti-scalding mask 240.

The shell element 210 has an accommodating space 201 and a metal surface 211, and the shell element 210 includes a plurality of fins 212. The electronic element 220 is disposed in an accommodating space 201. The printed circuit board 230 is disposed in the accommodating space 201 and is electrically connected to the electronic element 220. The anti-scalding mask 240 covers and is disposed on the metal surface 211. The anti-scalding mask 240 includes a plurality of vents 241, a sidewall structure 242 and a mask cover 243. Further, the electronic element 220, the printed circuit board 230, and the anti-scalding mask 240 are similar in structure to the electronic element 120, the printed circuit board 130, and the anti-scalding mask 140 of the electronic device 100, and the definitions of a first direction D1 and a second direction D2 of the electronic device 200 are also the same as that of the first direction D1 and the second direction D2 of the electronic device 100, so that the structures and details of the same elements can be referred to the description of the electronic device 100 and will not be repeated herein again.

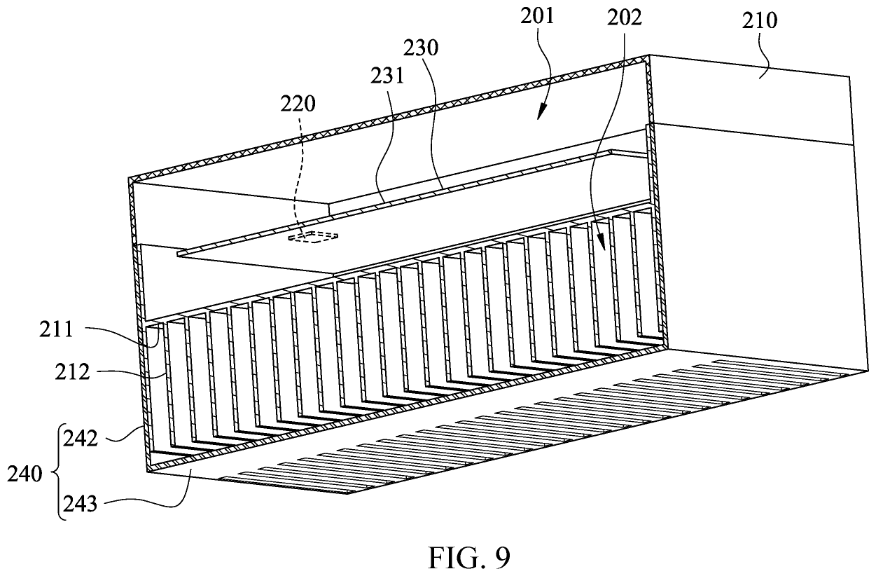

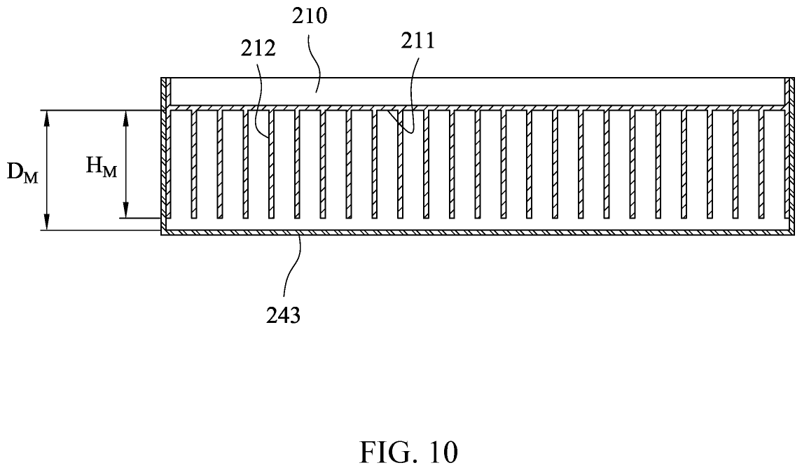

Reference is made to FIG. 7, FIG. 9, and FIG. 10 together. FIG. 9 is a cross-sectional view of the electronic device 200 as shown in FIG. 7 along Line 9-9. FIG. 10 is a schematic view of an arrangement of the fins 212 of the electronic device 200 as shown in FIG. 7. As shown in FIG. 9, one side of the sidewall structure 242 of the anti-scalding mask 240 is connected to the shell element 210, the mask cover 243 is connected to another side of the sidewall structure 242, a mask space 202 is defined by the shell element 210, the sidewall structure 242, and the mask cover 243, and the fins 212 are located in the mask space 202. By the arrangement that the fins 212 are located in the mask space 202, it is favorable for preventing the users from accidentally touching the fins 212 and causing scalds or cuts, and the appearance of the electronic device 200 also can be smoother and more beautiful.

As shown in FIG. 9, the fins 212 are separately disposed on the metal surface 211 of the shell element 210. Both the electronic element 220 and the printed circuit board 230 are disposed in the accommodating space 201 of the shell element 210. A circuit board surface 231 of the printed circuit board 230 faces a direction different from the fins 212. Therefore, when the electronic device 200 is operating, the heat generated by the electronic element 220 inside the shell element 210 will be transferred to the fins 212 through the metal surface 211 of the shell element 210 and then enters the anti-scalding mask 240. Then, the heat is dissipated though the vents 241 of the anti-scalding mask 240 by the thermal convection. Therefore, the heat dissipation performance of the electronic device 200 can be enhanced, and it is favorable for preventing the electronic device 200 from overheating and thus improving the performance of the electronic device 200.

As shown in FIG. 10 again, in the electronic device 200, the height of each of the fins 212 perpendicular to the metal surface 211 can be smaller than or equal to 200 mm. Further, as shown in FIG. 10, when a maximum height of the fins 212 perpendicular to the metal surface 211 is H_{M}, and a minimum distance between the mask cover 243 and the metal surface 211 is D_{M}, the following condition can be satisfied: 40%≤H_{M}/D_{M}≤100%. Therefore, the heat dissipation effect and the mechanical strength of the electronic device 200 can be effectively increased and the supporting function of the anti-scalding mask 240 can be taken into account simultaneously, but the present disclosure is not limited thereto.

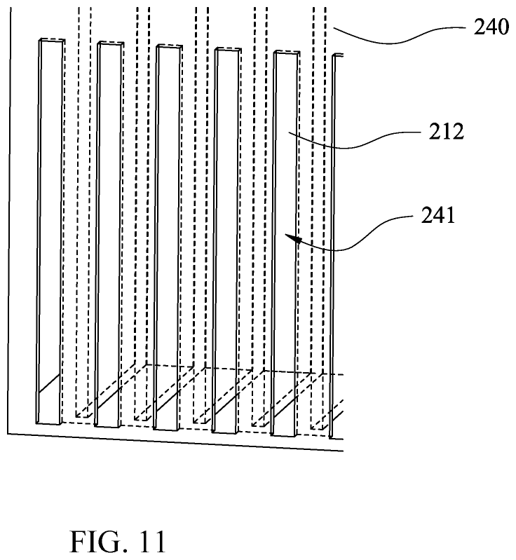

Reference is made to FIG. 10 and FIG. 11 together. FIG. 11 is an enlarged view of the arrangement of the fins 212 and the vents 241 of the electronic device 200 as shown in FIG. 7. As shown in FIG. 10 and FIG. 11, in some embodiments, the projected positions of the vents 241 along the first direction D1 are separated from the projected positions of the fins 212 along the first direction D1, and the projected positions of the vents 241 along the second direction D2 are separated from the projected positions of the fins 212 along the second direction D2. Specifically, in the electronic device 200, a distance between any two fins 212 adjacent thereto can be the same, and the vents 241 are separated from each other and equidistantly disposed on the anti-scalding mask 240. The projected positions of the vents 241 along the first direction D1 and the second direction D2 will not be overlapped with the projected positions of the fins 212 along the first direction D1 and the second direction D2. Therefore, each of the fins 212 is covered by the anti-scalding mask 240 and is not exposed from the vents 241, so that the fins 212 are not easily to be directly observed from the outer of the electronic device 200, and thus the aesthetics of the electronic device 200 can be enhanced. Furthermore, since the interval between any two fins 212 adjacent thereto is equivalent to the width of one of the vents 241 of the anti-scalding mask 240, the vents 241 are not blocked by the cross sections of the fins 212. Thus, the ventilating area of the vents 241 is maximized, and the heat dissipation performance of the anti-scalding mask 240 can be enhanced.

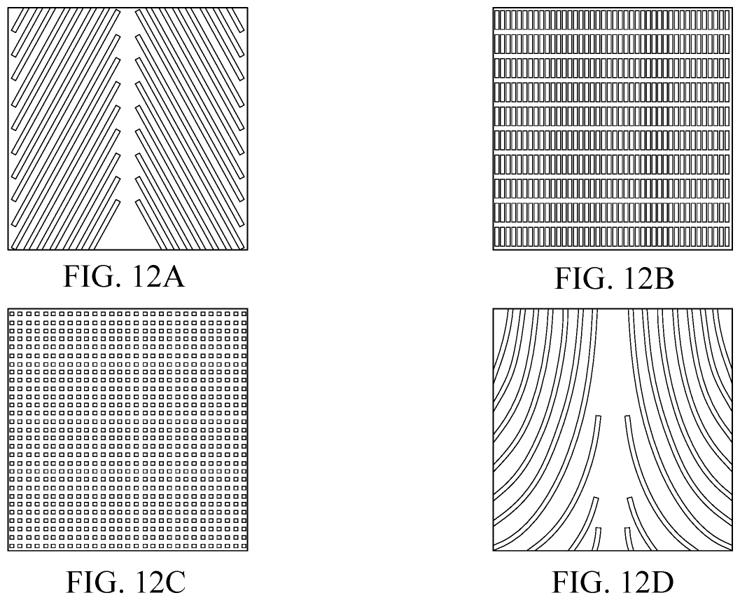

Reference is to FIG. 12A, FIG. 12B, FIG. 12C, and FIG. 12D. FIG. 12A is a schematic view of fins according to further another embodiment of the present disclosure. FIG. 12B is a schematic view of fins according to yet another embodiment of the present disclosure. FIG. 12C is a schematic view of fins according to yet another embodiment of the present disclosure. FIG. 12D is a schematic view of fins according to yet another embodiment of the present disclosure. As shown in FIG. 12A, FIG. 12B, FIG. 12C, and FIG. 12D, the fins 212 of the present disclosure can be the vertical fins as shown in FIG. 7, and the fins (reference number is omitted in FIG. 12A to FIG. 12D) of the present disclosure also can be the inclined fins as shown in FIG. 12A, the cross-cut fins as shown in FIG. 12B, the pin fins as shown in FIG. 12C, the rotating fins as shown in 12D, or the combination of the aforementioned fins as shown in FIG. 12A, FIG. 12B, FIG. 12C, and FIG. 12D, and the present disclosure is not limited thereto.

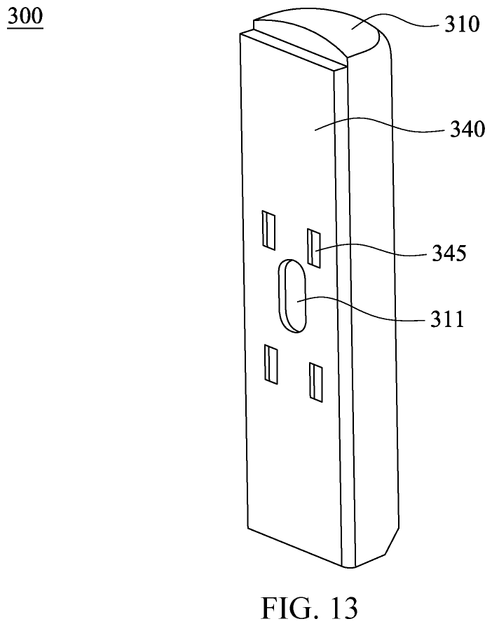

Reference is made to FIG. 13, which is a schematic view of an electronic device 300 according to yet another embodiment of the present disclosure. The electronic device 300 includes a shell element 310, at least one electronic element (not shown in the figure), a printed circuit board (not shown in the figure), and an anti-scalding mask 340. As shown in FIG. 13, the shell element 310 has a metal surface 311. The anti-scalding mask 340 covers the metal surface 311 so as to prevent the users from directly touching the metal surface 311 with high temperature. Furthermore, the anti-scalding mask 340 has a fixing hole 345, so that the anti-scalding mask 340 can be directly used as a hanging bracket for positioning the electronic device 300 to the wall, or can be directly used as a stand for hanging from the ceiling or standing on the table. Hence, the electronic device 300 of the present disclosure has outstanding potential market applications.

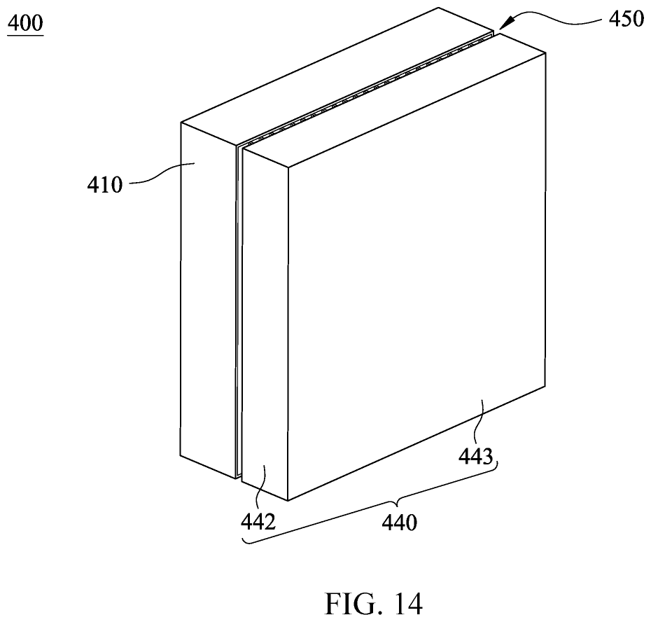

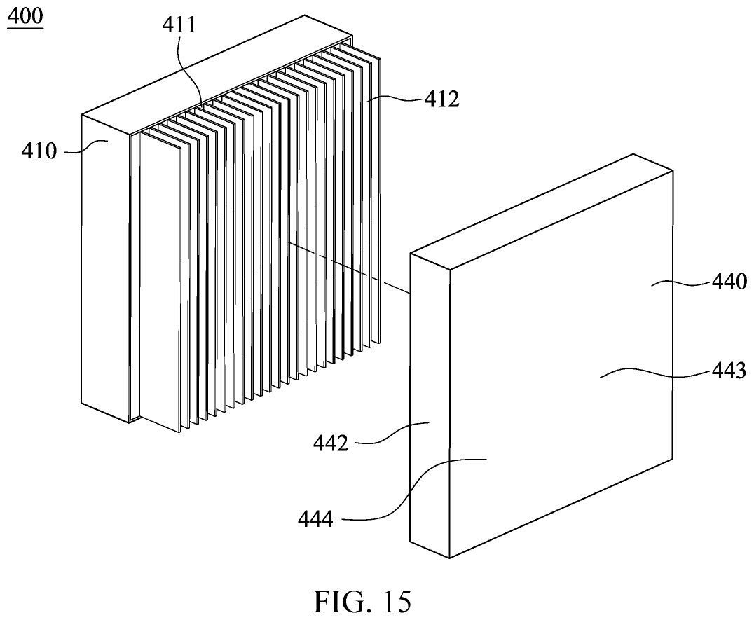

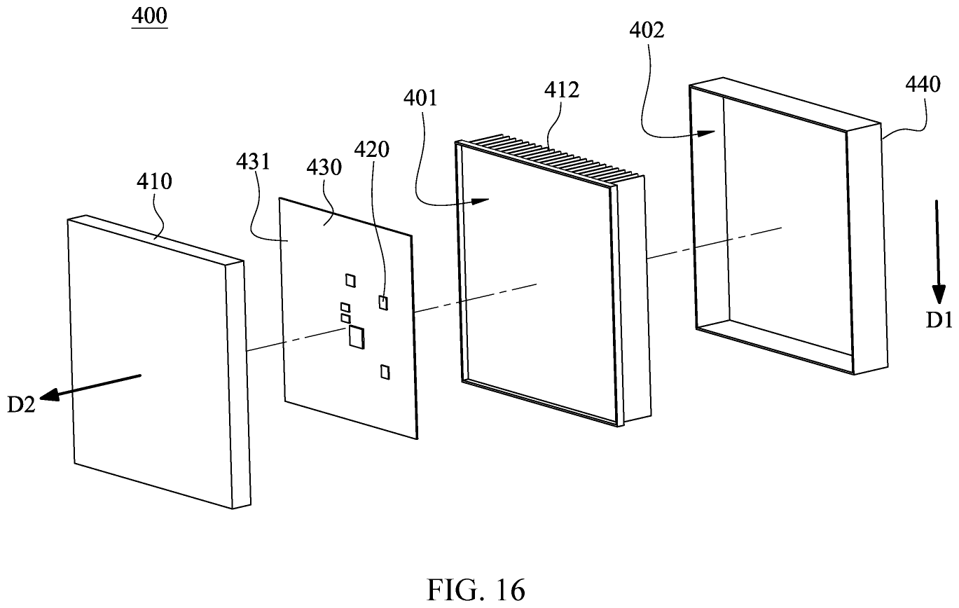

Reference is made to FIG. 14, FIG. 15, and FIG. 16. FIG. 14 is a schematic view of an electronic device 400 according to yet another embodiment of the present disclosure. FIG. 15 is an exploded view of the electronic device 400 as shown in FIG. 14. FIG. 16 is another exploded view of the electronic device 400 as shown in FIG. 14. The electronic device 400 includes a shell element 410, at least one electronic element 420, a printed circuit board 430, and an anti-scalding mask 440.

The shell element 410 has an accommodating space 401 and a metal surface 411, and the shell element 410 includes a plurality of fins 412. The electronic element 420 is disposed in the accommodating space 401. The printed circuit board 430 is disposed in the accommodating space 401 and is electrically connected to the electronic element 420. The anti-scalding mask 440 covers and is disposed on the metal surface 411. An air gap 450 is defined by a peripheral portion (reference is omitted) of the anti-scalding mask 440 and the shell element 410. Further, the electronic element 420 and the printed circuit board 430 are similar in structure to the electronic element 120 and the printed circuit board 130 of the electronic device 100, so that the structure and details of the same elements can be referred to the description of the electronic device 100 and will not be repeated herein again.

As shown in FIG. 14 to FIG. 16, the anti-scalding mask 440 includes a sidewall structure 442 and a mask cover 443. The mask cover 443 is connected to the sidewall structure 442. The sidewall structure 442 is extended from the mask cover 443 toward the shell element 410 and then is connected to the shell element 410. A mask space 402 is defined by the shell element 410, the sidewall structure 442, and the mask cover 443. The fins 412 are located in the mask space 402. The air gap 450 is defined by a peripheral portion of the sidewall structure 442 and the shell element 410, and the air gap 450 is communicated with the mask space 402.

Specifically, in the electronic device 400, the anti-scalding mask 440 is not abutted and connected to the metal surface 411 of the shell element 410. The air gap 450 is an unconnected gap between the sidewall structure 442 and the shell element 410. The fins 412 can be exposed from the electronic device 400 through the air gap 450. Therefore, when the electronic device 400 is operating, the heat generated by the electronic element 420 inside the shell element 410 can be transferred to the fins 412 through the metal surface 411 of the shell element 410 and then enters the anti-scalding mask 440. Then, the heat is dissipated through the air gap 450 between the anti-scalding mask 440 and the shell element 410 by the thermal convection. Therefore, the heat dissipation performance of the electronic device 400 can be enhanced, and it is favorable for preventing the overheating of the electronic device 400 and thus improving the performance of the electronic device 400.

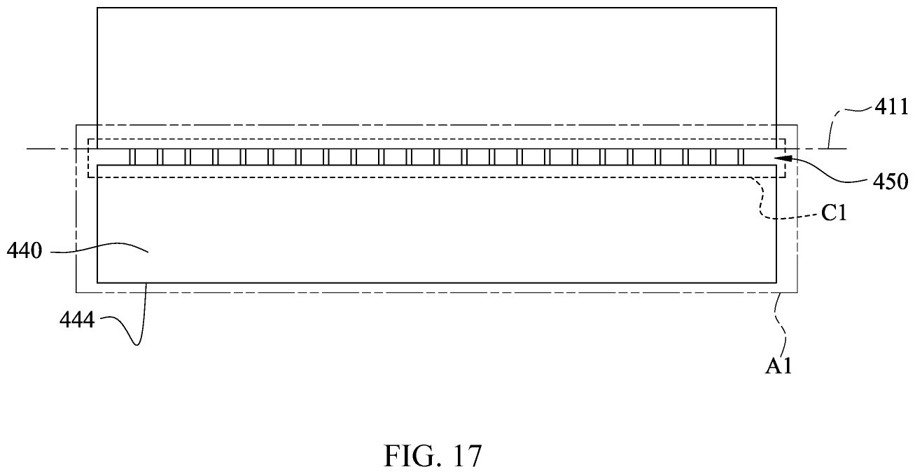

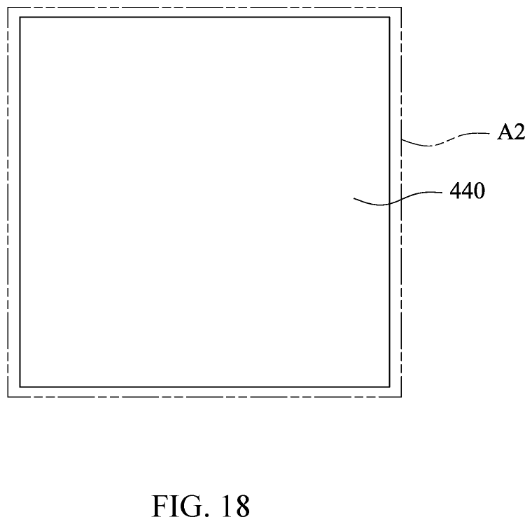

Reference is made to FIG. 16, FIG. 17, and FIG. 18. FIG. 17 is a schematic view of a projection of the electronic device 400 as shown in FIG. 14 along a first direction D1. FIG. 18 is a schematic view of a projection of the electronic device 400 as shown in FIG. 14 along a second direction D2. As shown in FIG. 16, FIG. 17, and FIG. 18, the electronic device 400 of the present disclosure defines the first direction D1 and the second direction D2. The second direction D2 is an extending direction perpendicular to a circuit board surface 431 of a printed circuit board 430, and the first direction D1 is perpendicular to the second direction D2. When a projected area of the anti-scalding mask 440 along the first direction D1 is A1, a projected area of the anti-scalding mask 440 along the second direction D2 is A2, a projected area of the air gap 450 along the first direction D1 is C1, and a projected area of the air gap 450 along the second direction D2 is C2, the following condition can be satisfied: 5%≤(C1+C2)/(A1+A2). Therefore, the anti-scalding mask 440 can have the effects of heat dissipation and anti-scalding as well as an excellent mechanical strength at once.

Specifically, in the electronic device 400, the air gap 450 surrounds and extends along the peripheral portion of the shell element 410. Under this condition, the projected area A1 of the anti-scalding mask 440 along the first direction D1 is a projected area from the metal surface 411 to a surface 444 of the anti-scalding mask 440 (as shown in FIG. 17, and the position of the surface 444 is shown in FIG. 15), so as to exclude the projected area where the anti-scalding mask 140 overlaps with the shell element 410. Further, the projected area C2 of the air gap 450 along the second direction D2 is zero, so that it is not able to see from the figure. However, in some embodiments, the shape of the anti-scalding mask 440 can be arc-shaped or polygonal, etc. In these cases, the projected area C2 of the air gap 450 along the second direction D2 may present different values, and the present disclosure is not limited thereto. Furthermore, in some embodiments, the number of the air gaps can be at least two, and the at least two air gaps are not communicated with each other and are respectively located at two opposite sides of the electronic device, but the disclosure is not limited thereto.

Furthermore, the fixation between the anti-scalding mask 140 and the shell element 410 can be achieved by a boss column on the metal surface 411 for the anti-scalding mask 140 to be locked. Hence, the effect that the anti-scalding mask 140 is suspended in the air can be obtained. Moreover, in some embodiments, a substructure with a fixing function can also be provided on the non-metal shell parts of the metal surface 411, the fins 412, or the shell element 410 for buckling or locking the anti-scalding mask 140, but the present disclosure is not limited thereto.

In summary, the advantages of the electronic device of the present disclosure are shown as follows. First, by covering and disposing an anti-scalding mask on the metal surface of the shell element, the electronic device of the present disclosure can prevent the users from directly touching the hot metal surface, so that the risk of accidental scald to the users can be effectively reduced. Second, by providing the anti-scalding mask with a plurality of vents or defining an air gap between the peripheral portion of the anti-scalding mask and the shell element, it is favorable for dissipating the heat generated during the operation of the electronic device though the vents by the thermal convection, and thus the overheating of the electronic device can be avoided and then the performance thereof can be enhanced. Third, by the arrangement that the shell element includes a plurality of fins disposed on the metal surface thereof, the heat dissipation efficiency of the electronic device can be effectively enhanced. Fourth, by the arrangement that the anti-scalding mask is made of a low thermal conductivity material with a thermal conductivity coefficient less than or equal to 20 W/mK, the electronic device of the present disclosure can comply with the touch temperature specifications specified by electronic product safety standards, so that the possibility of the users accidentally touching and getting scalded can be reduced. Fifth, when the ratios of the projected area of the anti-scalding mask and the vents or the air gaps thereof in different directions satisfy specific conditions, the effects of heat dissipation and scald prevention of the anti-scalding mask can be satisfied under the premise of an excellent mechanical strength, so that the electronic device of the present disclosure can have an outstanding market potential for various applications.

The foregoing description of the disclosure has been presented only for the purposes of illustration and description option of the exemplary embodiments and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An electronic device, comprising:
a shell element having an accommodating space and a metal surface;
at least one electronic element disposed in the accommodating space;
a printed circuit board disposed in the accommodating space and electrically connected to the at least one electronic element; and
an anti-scalding mask covering and disposed on the metal surface and comprising a plurality of vents;
wherein the anti-scalding mask is made of a low thermal conductivity material, and a thermal conductivity of the low thermal conductivity material is less than or equal to 20 W/mK.

2. The electronic device of claim 1, wherein the anti-scalding mask further comprises:
a sidewall structure with one side thereof connected to the shell element; and
a mask cover connected to another side of the sidewall structure, wherein a mask space is defined by the shell element, the sidewall structure, and the mask cover;
wherein at least one of the sidewall structure and the mask cover comprises the plurality of vents, and the plurality of vents are communicated with the mask space.

3. The electronic device of claim 2, wherein a projected area of the anti-scalding mask along a first direction is A1, a projected area of the anti-scalding mask along a second direction is A2, a projected area of the plurality of vents along the first direction is B1, a projected area of the vents along the second direction is B2, and the following condition is satisfied:
$$5 \% \leq ( B 1 + B 2 ) / ( A 1 + A 2 ) ,$$
wherein the second direction is perpendicular to a circuit board surface of the printed circuit board, the first direction is perpendicular to the second direction, and the projected area of the anti-scalding mask along the first direction is a projected area from the metal surface to a surface of the anti-scalding mask.

4. The electronic device of claim 3, wherein:
the anti-scalding mask has a first part and a second part, and the first part and the second part are arranged in sequence along the first direction; and
a projected area of the first part along the first direction is A11, a projected area of the first part along the second direction is A21, a projected area of the plurality of vents on the first part along the first direction is B11, a projected area of the plurality of vents on the first part along the second direction is B21, and the following condition is satisfied:
$$5 \% \leq ( B 11 + B 21 ) / ( A 11 + A 21 ) .$$

5. The electronic device of claim 4, wherein a projected area of the second part along the first direction is A12, a projected area of the second part along the second direction is A22, a projected area of the plurality of vents on the second part along the first direction is B12, a projected area of the plurality of vents on the second part along the second direction is B22, and the following condition is satisfied:
$$5 \% \leq ( B 12 + B 22 ) / ( A 12 + A 22 ) .$$

6. The electronic device of claim 2, wherein the plurality of vents are separated from each other and equidistantly disposed on the sidewall structure or the mask cover.

7. The electronic device of claim 2, wherein both the sidewall structure and the mask cover comprise the plurality of vents.

8. An electronic device, comprising:
a shell element having an accommodating space and a metal surface, the shell element comprising:
a plurality of fins separately disposed on the metal surface;
at least one electronic element disposed in the accommodating space;
a printed circuit board disposed in the accommodating space and electrically connected to the at least one electronic element; and
an anti-scalding mask covering and disposed on the metal surface and comprising a plurality of vents;
wherein the anti-scalding mask is made of a low thermal conductivity material, and a thermal conductivity of the low thermal conductivity material is less than or equal to 20 W/mK.

9. The electronic device of claim 8, wherein a height of each of the plurality of fins perpendicular to the metal surface is smaller than or equal to 200 mm.

10. The electronic device of claim 8, wherein the plurality of fins are vertical fins, inclined fins, transverse fins, needle fins, turning fins, or combinations thereof.

11. The electronic device of claim 8, wherein the anti-scalding mask further comprises:
a sidewall structure with one side thereof connected to the shell element; and
a mask cover connected to another side of the sidewall structure, wherein a mask space is defined by the shell element, the sidewall structure, and the mask cover, and the plurality of fins are located in the mask space;
wherein at least one of the sidewall structure and the mask cover comprises the plurality of vents, and the plurality of vents are communicated with the mask space.

12. The electronic device of claim 11, wherein a projected area of the anti-scalding mask along a first direction is A1, a projected area of the anti-scalding mask along a second direction is A2, a projected area of the plurality of vents along the first direction is B1, a projected area of the plurality of vents along the second direction is B2, and the following condition is satisfied:
$$5 \% \leq ( B 1 + B 2 ) / ( A 1 + A 2 ) ,$$
wherein the second direction is perpendicular to a circuit board surface of the printed circuit board, the first direction is perpendicular to the second direction, and the projected area of the anti-scalding mask along the first direction is a projected area from the metal surface to a surface of the anti-scalding mask.

13. The electronic device of claim 12, wherein
the anti-scalding mask has a first part and a second part, and the first part and the second part are arranged in sequence along the first direction; and
a projected area of the first part along the first direction is A11, a projected area of the first part along the second direction is A21, a projected area of the plurality of vents on the first part along the first direction is B11, a projected area of the plurality of vents on the first part along the second direction is B21, and the following condition is satisfied:
$$5 \% \leq ( B 11 + B 21 ) / ( A 11 + A 21 ) .$$

14. The electronic device of claim 13, wherein a projected area of the second part along the first direction is A12, a projected area of the second part along the second direction is A22, a projected area of the plurality of vents on the second part along the first direction is B12, a projected area of the plurality of vents on the second part along the second direction is B22, and the following condition is satisfied:
$$5 \% \leq ( B 12 + B 22 ) / ( A 12 + A 22 ) .$$

15. The electronic device of claim 12, wherein projected positions of the plurality of vents along the first direction are separated from projected positions of the plurality of fins along the first direction, and projected positions of the plurality of vents along the second direction are separated from projected positions of the plurality of fins along the second direction.

16. The electronic device of claim 11, wherein both the sidewall structure and the mask cover comprise the plurality of vents.

17. The electronic device of claim 11, wherein a maximum height of the plurality of fins perpendicular to the metal surface is H_{M}, a minimum distance between the mask cover and the metal surface is D_{M}, and the following condition is satisfied:
$$40 \% \leq {H}_{M} / {D}_{M} \leq 100 \% .$$

18. An electronic device, comprising:
a shell element having an accommodating space and a metal surface, the shell element comprising:
a plurality of fins separately disposed on the metal surface;
at least one electronic element disposed in the accommodating space;
a printed circuit board disposed in the accommodating space and electrically connected to the at least one electronic element; and
an anti-scalding mask covering and disposed on the metal surface, wherein an air gap is defined by a peripheral portion of the anti-scalding mask and the shell element;
wherein the anti-scalding mask is made of a low thermal conductivity material, and a thermal conductivity of the low thermal conductivity material is less than or equal to 20 W/mK.

19. The electronic device of claim 18, wherein the anti-scalding mask comprises:
a sidewall structure; and
a mask cover connected to the sidewall structure, wherein the sidewall structure is extended from the mask cover and then connected to the shell element, and the air gap is defined by a peripheral portion of the sidewall structure and the shell element;
wherein a mask space is defined by the shell element, the sidewall structure, and the mask cover, the plurality of fins are located in the mask space, and the air gap is communicated with the mask space.

20. The electronic device of claim 19, wherein a projected area of the anti-scalding mask along a first direction is A1, a projected area of the anti-scalding mask along a second direction is A2, a projected area of the air gap along the first direction is C1, a projected area of the air gap along the second direction is C2, and the following condition is satisfied:
$$5 \% \leq ( C 1 + C 2 ) / ( A 1 + A 2 ) ,$$
wherein the second direction is perpendicular to a circuit board surface of the printed circuit board, the first direction is perpendicular to the second direction, and the projected area of the anti-scalding mask along the first direction is a projected area from the metal surface to a surface of the anti-scalding mask.
